(19) United States
(12) Patent Application Publication
(10) Pub. No.: US 2023/0169643 A1
(43) Pub. Date: Jun. 1, 2023

(54) MONITORING OF DEPOSITED OR ETCHED FILM THICKNESS USING IMAGE-BASED MASS DISTRIBUTION METROLOGY

(71) Applicant: Applied Materials, Inc., Santa Clara, CA (US)

(72) Inventors: Mehdi Vaez-Iravani, Los Gatos, CA (US); Todd J. Egan, Fremont, CA (US)

(21) Appl. No.: 18/070,114

(22) Filed: Nov. 28, 2022

Related U.S. Application Data
(60) Provisional application No. 63/284,190, filed on Nov. 30, 2021.

(51) Int. Cl. G06T 7/00; G01B 21/08; B25J 9/16; G06T 7/60

(52) U.S. Cl. CPC G06T 7/001; G01B 21/08; B25J 9/1697; G06T 7/60; G06T 2207/10152; G06T 2207/30148

(57) ABSTRACT

Implementations disclosed describe a method of obtaining a first image of a sample using a first light, wherein the sample has been subjected to a processing operation associated with a change of a thickness of the sample. The method further includes weighing the sample to obtain a first mass of the sample. The method further includes determining, based at least in part on the first image of the sample and the first mass of the sample, one or more properties of the sample, such as the change of a thickness of the sample, a change of an refractive index of the sample, and/or a change of an optical density of the sample a distribution of the change of the thickness of the sample.

### RELATED APPLICATIONS

This application claims the benefit of U.S. Provisional Application No. 63/284,190, filed Nov. 30, 2021, the entire contents of which are incorporated herein by reference.

### TECHNICAL FIELD

This instant specification generally relates to ensuring quality control of materials manufactured in substrate processing systems. More specifically, the instant specification relates to optical techniques to monitor mass distribution of substrates during various stages of the manufacturing process.

### BACKGROUND

Manufacturing of modern materials often involves various deposition techniques, such as chemical vapor deposition (CVD) or physical vapor deposition (PVD) techniques, in which atoms of one or more selected types are deposited on a substrate (wafer) held in low or high vacuum environments that are provided by vacuum deposition chambers. Materials manufactured in this manner may include monocrystals, semiconductor films, fine coatings, and numerous other substances used in practical applications, such as electronic device manufacturing. Many of these applications rely on the purity and uniformity of the materials grown in substrate processing systems. The need to maintain isolation of the inter-chamber environment and to minimize its exposure to ambient atmosphere and contaminants therein gives rise to various robotic techniques of sample manipulation and inspection. Improving precision, reliability, and efficiency of such robotic techniques presents a number of technological challenges whose successful resolution facilitates continuing progress of electronic device manufacturing. Enhanced sophistication of robotic technology helps to meet the constantly increasing demands to the quality of chamber manufacturing products.

### BRIEF DESCRIPTION OF THE DRAWINGS

FIG. 1 illustrates one exemplary embodiment of a manufacturing machine capable of supporting a mass metrology system to monitor film thickness changes during a processing operation, according to one embodiment.

FIG. 2A illustrates a mass metrology system that includes an imaging device, a weighing module, and a processing tool, according to one embodiment.

FIG. 2B illustrates integration of machine-learning methods of monitoring film thickness with optical and mass metrologies, according to one embodiment.

FIG. 3 is a flow diagram of a method of determining a mass distribution of a sample according to one embodiment.

FIG. 4 depicts a block diagram of an example processing device operating in accordance with one or more aspects of the present disclosure.

### DETAILED DESCRIPTION

The embodiments disclosed herein provide for using mass distribution metrology for monitoring film thickness of substrates and wafers due to non-uniformities resulting from wafer manufacturing processes including polishing, etching, material deposition, and the like. For example, the embodiments disclosed may enable to determine non-uniformities due to deposition or etching by mapping mass distribution on wafers using methods that may be integrated into larger processing tools, such as chemical-mechanical polishing (CMP) instruments. For example, mapping mass distributions may include weighing the wafer and obtaining an image of the wafer both before (prior to) and after a specific technological process, such as deposition and/or etching. This may allow for determination of how much the mass has changed, as well as where on the substrate the changes are occurring. Further, once the mass distribution is known, the metrology data may indicate how to best correct undesirable thickness variations and create as uniform a surface as possible (or achieve other target thickness variations as may be specified by a technological process being performed).

Determining mass distribution and changes of mass distribution on a wafer may be relevant in many disciplines of technical and commercial interest, including production of flat semiconductor wafers (e.g., optical flats). During the manufacturing process of optical flats and semiconductor wafers, substances may not be distributed evenly across the wafer. For example, during a deposition process, some regions of the wafer may have more material deposited than another region, resulting in some regions being thicker or thinner. Such information may be made available by mapping mass distributions. Monitoring mass distributions may be useful for various manufacturing operations (e.g., CMP operations, deposition, etching, other material removal, and the like) performed on semiconductor wafers, in which the objective is to produce a wafer that is as flat and uniform as possible.

Accordingly, it may be advantageous to have information regarding mass distributions across the surface, which may relate to its quality, roughness, and so on, before (prior to), during, and/or after a processing operation is complete, to enable correction of processing errors and imperfections while a sample is still inside the processing system. In some embodiments, the target surface may have a complicated profile that includes a number of ridges, recesses, kinks, grooves, flat regions, rounded regions, and so on. For example, a thickness profile of the wafer surface may be represented by a dependence of a height (width, depth) of the target surface h(x, y), counted from some reference surface (e.g., a horizontal or a vertical plane), on the coordinates (e.g., x, y) along this reference surface. The profile may be characterized by a discrete (or a quasi-continuous) set of locations with the resolution determined by a spacing (e.g., Δx, Δy) between adjacent locations. The spacing may be pre-set based on the desired resolution of the target surface imaging.

Existing techniques to map thickness variations during various stages of a fabrication process of a substrate or a wafer include reflectometers, ellipsometers, optical critical dimension (OCD) measuring systems, high-resolution scanning, transmission electron microscopes (TEMs), and atomic force microscopes (AFMs). These solutions, however, often require detailed knowledge of the structures in addition to sophisticated modeling capabilities. As described herein, one advantageous and time-efficient solution is to supplement optical sensing data with mass metrology data, given the difficulty associated with extracting exact or precise information about thickness changes (due to processes such as depositing films or removing material) by a sole use of optical instruments.

Because mass is a universal scalar quantity, its determination may be performed by techniques and systems that are applicable to all samples, regardless of size, chemical and physical composition, and specifics of technological processing. Mass metrology may be used to determine how much material has been added during a deposition process or how much material has been removed during etching or polishing. However, global mass metrology provides a value representative of the whole substrate, e.g., a mass of the entire substrate, or a change in the mass of the substrate before and after a processing operation. Existing mass metrology tools alone may be incapable of determining the uniformity of the substrate after a material deposition or a material removal (such as polishing or etching) operation performed during the wafer manufacturing process. Thus, there is a need for a solution to use mass metrology to produce a measure of the uniformity of the processes.

Aspects and embodiments of the present disclosure address these and other shortcomings of the existing technology. Described herein is a method and setup for a mass metrology system for combining mass metrology and optical imaging techniques to determine mass distributions and to enable monitoring film thickness and its variations. Adding or removing materials (such as metals, dielectrics, and the like) to a wafer alters the mass of the wafer as well as the nature of the optical behavior of the wafer. The change in mass provides information regarding how much material has been added or removed, while the change in the optical characteristics may provide an image or a map of the surface of the wafer. By combining these two pieces of information, a mass distribution across two or more locations the wafer may be determined, and subsequently a thickness profile across the wafer or another benchmark of the accuracy of wafer processing may be identified. Information about the uniformity and quality of a processing operation may be deduced by determining and comparing mass distributions before and after the processing operation. Specific regions of the wafer can be targeted, and uniformity signatures can be provided. Furthermore, specific films and geometries of interest in a complex structure can be targeted. The mass metrology system may be integrated into a port of a semiconductor processing tool. Therefore, mass metrology combined with optical imaging may provide information that facilitates improving the quality of manufacturing processes of substrates and wafers and that is not available from separate applications of the mass metrology and optical imaging techniques. Mass metrology may be implemented without the requirement of complex models. Furthermore, mass metrology may be less sensitive to variability of substrate shape, while still providing information of variations of optically obscured and/or opaque structures.

For example, measuring a change in mass before and after a process operation can function as a cross-check for optical measurements. In some embodiments, a distribution of mass change (or thickness change) may be measured before and after a processing operation. Mass measurements can also be used to pre-screen for time-consuming optical measurements. Furthermore, an optical model may be tuned one embodiment optimized based on a change of mass (e.g., certain parameters of a complex optical model may be simplified or altogether fixed to one or more known values). In some embodiments, an unexpected change in the measured mass may be used to select aberrant substrates for optical metrology to identify one or more aberrant regions on the substrate.

The disclosed embodiments pertain to a variety of manufacturing techniques that use processing chambers (that may include deposition chambers, etching chambers, and the like), such as chemical mechanical polishing (CMP) techniques, chemical vapor deposition techniques (CVD), physical vapor deposition (PVD), plasma-enhanced CVD, plasma-enhanced PVD, sputter deposition, atomic layer CVD, combustion CVD, catalytic CVD, evaporation deposition, molecular-beam epitaxy techniques, and so on. Although the most significant practical impact of the disclosed embodiments may be expected to occur in techniques that use vacuum deposition chambers (e.g., ultrahigh vacuum CVD or PVD, low-pressure CVD, etc.), the same systems and methods may be utilized in atmospheric pressure deposition chambers for non-intrusive monitoring of the chamber conditions that exist during deposition processes.

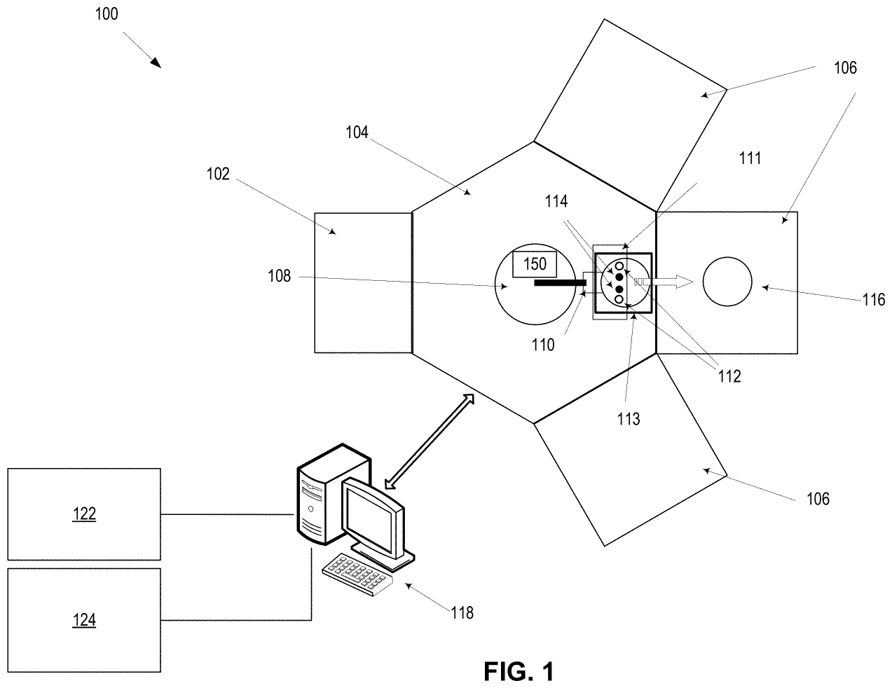

FIG. 1 illustrates one exemplary embodiment of a manufacturing machine 100 capable of supporting a mass metrology system to monitor film thickness changes during a processing operation, according to one embodiment. In one embodiment, the manufacturing machine 100 includes a loading station 102, a transfer chamber 104, and one or more processing chambers 106. The processing chamber(s) 106 may be interfaced to the transfer chamber 104 via transfer ports (not shown). The number of processing chamber(s) associated with the transfer chamber 104 may vary (with three processing chambers indicated in FIG. 1 as a way of example). The transfer chamber 104 may include a robot 108, a movable robot blade 110 to support a substrate (e.g., a wafer or a transparent wafer), light source(s) 112 for scanning of a substrate 116 (e.g., a target), optical sensors 114, and a weighing station 113, which may be located in one of the processing chambers 106 or the transfer chamber 104. The light source(s) 112, the optical sensors 114, and the weighing station 113 may be part of a mass metrology system 111. In some embodiments, the weighing station 113 may be a mass measurement device, such as scale, a spring scale, a balance, or the like. The weighing station 113 may be mechanical or electronic. The weighing station 113 may be calibrated in units of force (e.g., Newtons), while other weighing stations may be calibrated in units of mass (e.g., grams). The transfer chamber 104 may be held under pressure (temperature) that is higher (or lower) than the atmospheric pressure (temperature).

The robot 108 may transfer various products and devices (e.g., semiconductor wafers, substrates, liquid crystal displays, reticles, calibration devices) between the loading station 102 and one of the processing chambers 106.

In one embodiment, the robot blade 110 of the robot 108 supports the substrate 116 when the latter is transferred into one of the processing chambers 106. The robot blade 110 may be attached to an extendable arm sufficient to reach between different chambers. The light source(s) 112 may scan the substrate 116 with one or more beams of light to obtain an image of a substrate. In some embodiments, the image may be of the substrate 116 that has been subjected to a processing operation, such as material deposition operation or material removal operation (e.g., polishing or etching). In some embodiments, multiple images of the substrate 116 may be obtained, for example before and after the substrate 116 has been subjected to the processing operation. The image(s) may be based on determining a reflectivity or a transmissivity map of the substrate, which may be obtained by the optical sensors 114 receiving light from the light source(s) 112 that is reflected by (or transmitted through) the substrate 116. The substrate 116 may be a wafer, a substrate chuck, an edge ring, or any other object/tool located in one of the processing chambers 106 (or in the loading station 102, the transfer chamber 104, the ports connecting the transfer chamber 104 to the loading station 102 or the processing chambers 106). The mass metrology system 111 may include an alignment point in order to be properly aligned relative to the substrate 116. The alignment point may be a hole, notch, or indent and may be centered in a pocket or depression of the robot blade 110. The optical sensors 114 of the mass metrology system 111 may be capable of sensing visible light or other electromagnetic radiation coming from the target surface (e.g. reflected by that surface) of the substrate 116. The light detected by the optical sensors 114 may be reflected from the target surface where the light may be directed by one or more light sources 112. In some embodiments, the light sources 112 may be mounted on the same mass metrology system 111. In other embodiments, the light source(s) 112 may be located outside the mass metrology system 111, e.g., mounted inside the transfer chamber 104, the loading station 102 or the processing chambers 106. In some embodiments, the mass metrology system 111 may be in an enclosed chamber which is integrated into a port of a semiconductor processing tool, and a space above the mass metrology system 111 may include a transparent window, such that it may transmit, with negligible (or known) loss, light (or electromagnetic radiation) at wavelengths of interest. In one embodiment, a multi-spectral imaging system may be located above the transparent window, and may be capable of imaging the entire substrate at once. In other embodiments, a multi-spectral imaging system that provides a smaller field of view may be used, and the substrate may be scanned by moving an optical head (of the multi-spectral imaging system) together with the field of view relative to the substrate, such that an image of the entire substrate may be obtained. In other embodiments, the scanning of the substrate does not need to cover the entire substrate, for example, when an image of only a portion of the substrate is needed (e.g., of only a portion that has been subjected to a processing operation).

The robot blade 110 may deliver (and retrieve) substrates to (and from) the processing chamber(s) 106 through a slit valve port (not shown) while a lid to the processing chamber(s) 106 remains closed. The processing chamber(s) 106 may contain processing gases, plasma, and various particles used in deposition processes. A magnetic field may exist inside the processing chamber(s) 106. The inside of the processing chamber(s) 106 may be held at temperatures and pressures that are different from the temperature and pressure outside the processing chamber(s) 106. The temperatures and pressures inside the processing chamber(s) 106 may be similar to those that correspond to the actual on-line processing conditions.

A computing device 118 may include an optical sensor control module 122 and the mass analysis module 124. The optical sensor control module 122 may operate the optical sensors 114 and, in some cases, the light source(s) 112. The mass analysis module 124 may receive mass measurements from the weighing station 113. The optical sensor control module 122 and the mass analysis module may be used to determine a mass distribution and/or thickness distribution (e.g., mass density and/or thickness of the substrate at two or more locations) of the substrate 116, for example, before and after a processing operation.

The electronics module 150 may be capable of facilitating wireless mass distribution mapping of targets inside the manufacturing machine 100 to determine thickness profiles of the substrate, in one exemplary embodiment. The electronics module 150 may include a microcontroller and a memory buffer coupled to the microcontroller. The memory buffer may be used to collect and store data before transmitting the data to the computing device 118. In some embodiments, the data may be transmitted using a wireless communication circuit. In other embodiments, the data may be transmitted using a wired connection between the electronics module 150 and the computing device 118. In some embodiments, the data may first be stored (buffered) in the memory buffer prior to being transmitted to the computing device 118. In other embodiments, the data may be transmitted to the computing device 118 as the data is collected, without being stored in the memory buffer. In some embodiments, the wireless or wired connection may be continuous. In other embodiments, the wireless or wired connection may be established periodically or upon completion of the inspection or some other triggering event (e.g., when the memory buffer is close to being full). The electronics module 150 may further include a power element and a power-up circuit. In some embodiments, the power element may be a battery. In some embodiments, the power element may be a capacitor. The power element may be rechargeable from a power station. The microcontroller may be coupled to one or more optical sensors 114. The optical sensor 114 may include a light source and a light detector. The electronics module 150 may also include an accelerometer to facilitate accurate extension and angular rotation of the robot blade 110. The electronics module 150 may also include a temperature sensor to detect temperature near the substrate 116.

The electronics module 150 may further include a wireless communication circuit, i.e. a radio circuitry for receiving wireless instructions from the computing device 118 and for transmitting intensity values to the computing device 118. For example, the radio circuitry may include a radio-frequency (RF) front end module and an antenna (e.g., an ultra-high frequency (UHF) antenna), which may be an internal ceramic antenna, in one embodiment. The batteries may be of a high temperature-tolerant type such as lithium ion batteries that may be exposed to a chamber temperature of 450 degrees Celsius (C) for a short time period such as one to eight minutes.

Some components may be located on or at the stationary part of the robot 108. For example, the microcontroller, the memory buffer, and the RF front end may be so located. Other components of the electronics module 150 may be located on or at the robot blade 110 of the robot 108 and or the mass metrology system supported by the robot blade. The robot blade may be movable to support a substrate, which may be transported by the moveable robot blade. For example, the optical sensors 114, the accelerometer, and the temperature sensor may be so located. In some embodiments, some of the components of the electronics module 150 may be located both at the stationary part of the robot 108 and the extendable robot blade 110, e.g., the power element may be so located. In some embodiments, two separate microcontrollers may be implemented, with one of the microcontrollers located on the stationary part of the robot 108 and the other microcontroller located on the mass metrology system 111.

The wireless connection facilitated by the RF front end and antenna may support a communication link between the microcontroller and the computing device 118, in some embodiments. In some embodiments, the microcontroller integrated with the robot 108 may have a minimal computational functionality sufficient to communicate information to the computing device 118, where most of the processing of information may occur. In other embodiments, the microcontroller may carry out a significant portion of computations, while the computing device 118 may provide computational support for specific, processing-intensive tasks. Data received by the computing device 118 may be data obtained from the inside of the transfer chamber 104, the processing chambers 106, data collected by the optical sensors 114, data temporarily or permanently stored in the memory buffer, and so on. The data stored in the memory buffer and/or transmitted to or from the computing device 118 may be in a raw or processed format.

In one embodiment, mass metrology system 111 may determine (using the processing capabilities of the microcontroller and/or the computing device 118) profile data characterizing a thickness profile of the substrate based on masses of the substrate and optical images of the substrate associated with one or more received beams of light.

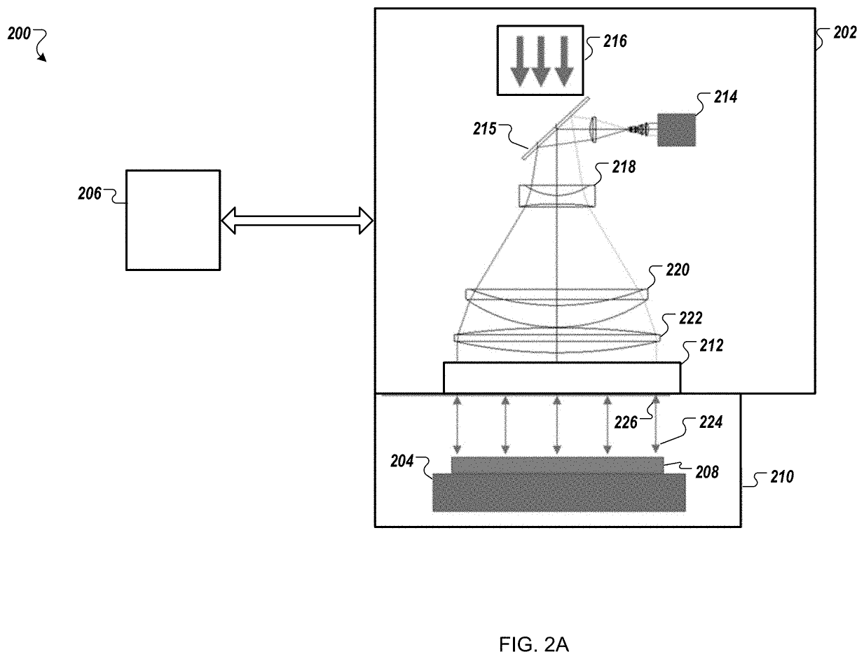

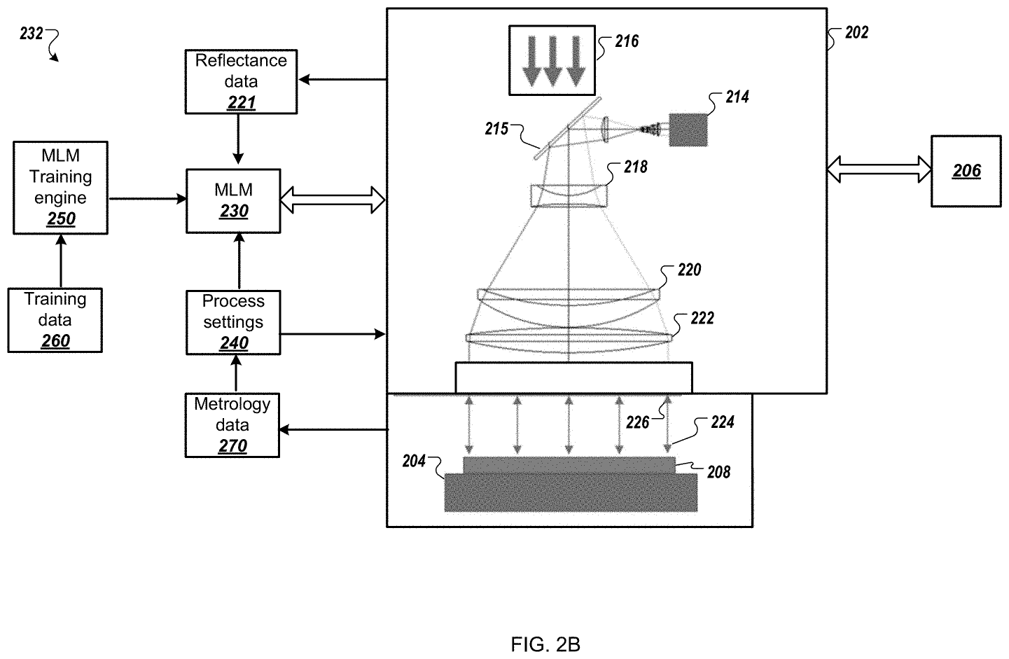

FIG. 2A illustrates an example mass metrology system 200 that includes an imaging device 202, a weighing module 204, and a processing device 206, according to one embodiment. The mass metrology system 200 may be used in substrate manufacturing machines, e.g., as the mass metrology system 111 of FIG. 1.

The mass metrology system 200 may provide a measure of uniformity of one or more processing operations that a substrate 208 may be subjected to. Common processing operations may include depositing metal, semiconductor, or dielectric materials onto the substrate 208 and/or removing metal, semiconductor, or dielectric materials from the substrate 208, often on the order of a few tens of nanometers in thickness. In some embodiments, the substrate 208 is a silicon carbide (SiC) wafer. In other embodiments, the wafer may be another material such as crystalline or amorphous silicon (Si) or the like. When even a thin layer of material is deposited onto or removed from the substrate 208, the nature of the optical response of the substrate is altered. For example, the reflectance or transmission of light from/through the substrate may be affected. Additionally, optical responses of the substrate may vary for different wavelengths of light. Therefore, spectral changes in the reflectance or transmission of light may be used as a representation of a change in thickness due to processing operations, such as deposition, polishing, or etching.

Due to potential non-uniformity of processing operations, thickness changes may be different across the surface of the substrate 208. In some embodiments, if the thickness changes due to the processing operations result in uneven adding or removing of material, the substrate 208 may be subjected to one or more additional processing operations to produce a more uniform surface. In some embodiments, additional material may be added or removed from the entire surface of the substrate. In other embodiments, additional material may be added to one or more regions of the substrate, while material may be removed from one or more other regions of the substrate. In some embodiments, deposition of materials on a substrate 208 may cause the substrate to weigh more and may cause the substrate to be slightly deformed by being bowed or warped. For example, there may be warping of the substrate due to compressive or tensile stress applied by the deposited films. In some cases, additional warping (drooping) may be caused by the lift pins that lift the substrate during processing. Thus, to correct such a deformation, an additional material may be added or removed to compensate for the warping.

In the depicted embodiment, the substrate 208 may be located or placed in an enclosed chamber 210 (e.g., by a robot blade of a robot, not depicted in FIG. 2A). The enclosed chamber 210 may include a transparent window 212 through which light (or other electromagnetic radiation at the wavelength(s) of interest) from the imaging device 202 may be transmitted with negligible (or controlled) loss. The imaging device 202 may be configured to obtain one or more images of the substrate. The imaging device 202 may be an imaging reflectometer, a spectrophotometer, a transmission spectrometer, and the like. The imaging device 202 may be located directly above the transparent window 212. The imaging device 202 may include a detector 214 (e.g., an imaging detector), a light source 216, and a number of other optical elements, such as including a beam splitter 215, an expander lens 218, one or more large field-of-view lenses 220 and 222, and so on. In one embodiment, light produced by the light source 216, transmitted by beam splitter 215, and directed by lenses 218, 220, and 222 may be incident (depicted schematically with rays 224) on the substrate 208 at a normal angle of incidence.

In the imaging device 202, light from the light source 216 may be passed through the beam splitter 215 and continue on an optical path toward the substrate 208. The light that is passed through the beam splitter 215 may be imaged by large-field lenses 220 and 222. The large-field lenses 220 and 222 may be telecentric lenses so that light rays traveling from the lenses to the substrate are approximately parallel to an optical axis that is substantially perpendicular to a surface of the substrate 208. In some embodiments there may be additional lenses that may serve to shape and/or direct the light along optical paths to illuminate the substrate 208 and to direct the reflected light to the detector 214. In some embodiments, the light may pass through one or more polarizers to provide enhanced sensitivity and SNR. In some embodiments, wave plates may be included to alter the phase of the polarized light. The wave plates and/or polarizers may be at fixed angles to provide polarized reflectometry measurements, or they may be rotating to provide ellipsometry measurements.

The light source 216 may be a multi-wavelength light source that may generate beams of light having different nominal wavelengths. In some embodiments a power associated with each wavelength of light may be independently controlled, which may allow for optimizing the dynamic range of measuring the reflectance images at each wavelength.

The substrate 208 may be positioned on top of the weighing module 204. The weighing module 204 may be designed to determine a mass of the substrate 208. In some embodiments, the weighing module 204 may be any mass measuring device, such as a scale, a spring scale, a balance, or the like. The weighing module 204 may be a mechanical module, and electronic module, or a combined mechanical-electronic module. The weighing module 204 may be calibrated in units of force (e.g., Newtons), while other weighing modules may be calibrated in units of mass (e.g., grams). In some embodiments, the weighing module 204 may be integrated as part of the robot blade. In other embodiments, the weighing module 204 may be separate from the robot blade, and may be positioned elsewhere in the enclosed chamber 210. In other embodiments, the weighing module 204 may be located outside the enclosed chamber 210, and may be calibrated to determine the mass of the substrate 208 by subtracting the weight of the enclosed chamber 210. In some embodiments, the substrate 208 may be placed directly on the weighing module 204. In some embodiments, the substrate 208 may be placed in any other way (e.g., supported by pins) that allows the substrate 208 to be weighed by the weighing module 204. The light reflected from the substrate 208 (depicted schematically with rays 226) may pass through the transparent window 212, be collected by lenses 220 and 222, narrowed by lens 218, and directed by the beam splitter 215 into the detector 214. In some embodiments, to eliminate back reflection of light that passed through the substrate 208, the surface of the weighing module 204 may be made of an absorbing material.

The imaging device 202 may include a selection of high-power light-emitting diodes (LEDs) from the light source 216. The LEDs may be sequentially pulsed and synchronized with a frame rate of the detector 214. The detector 214 may be a digital sensor, such as a complementary metal-oxide-semiconductor (CMOS) camera, a charge-coupled device (CCD) camera, or the like. A reflectance image of the substrate 208 may be obtained for each pulse of light, from the light source 216. The reflectance image may be obtained by the imaging device 202 or other imaging devices such as an imaging reflectometer. Reflectance images may be obtained before and after the processing operation. Separate reflectance images may be obtained for different wavelengths of light (e.g., monochromatic light), or lights with different spectral distributions, or the like. Each of the reflectance images taken for the successive pulses of each LED light may be averaged and stored, for example in a memory device, a memory buffer, or the like. For a given wavelength of light, multiple reflectance images of the substrate may be obtained to improve signal-to-noise ratio (e.g., by averaging the multiple obtained reflectance images). The spectrum of light may include a broadband spectrum, a filtered (narrowband) spectrum (e.g., using band-pass filters), or discrete wavelengths. In the case of discrete wavelengths, actual wavelengths used and the number of wavelengths used may depend on the specific application and may include any number, such as six, eight, ten, etc. In some embodiments, the multiple reflectance images may be combined and averaged to enhance a signal-to-noise ratio (SNR). In some embodiments, rather than obtaining reflectance images, transmission images may be obtained. Because the substrate 208 may be maintained in a fixed position during the imaging process, the obtained reflectance images may be exactly matched in position and/or magnification (or substantially matched within a target error or a threshold positioning/magnification error), which may allow for generating spectral information per pixel (e.g., of the detector 214) for the entire substrate 208. Such spectral information may be generated in a short amount of time (e.g., on the order of a few seconds or less).

Even though the above description uses, as an illustration, a reflectometer setup, similar measurements may be performed in transmission if the substrate 208 is at least partially transparent. In such embodiments, the weighing module 204 may be made of a transparent (or at least partially transparent) material (e.g., glass) and the detector 214 (together with a set of receiving lenses) may be positioned below the enclosed chamber 210.

In order to determine variations in thickness of the substrate 208, a mass measurement may be included via the weighing module 204. The variation in thickness may be determined based on a mass distribution, which may itself be determined based on the reflectance (or transmittance) images and a measured mass of the substrate 208. In particular, a measure of the uniformity of a processing operation (deposition, etching, polishing, and/or the like), may be determined by taking measurements before the processing operation and after the processing operation. For example, the mass metrology system 200 may provide a precise measurement of the total amount of material added or removed, while at the same time, providing a map representing the uniformity of the processing operation.

Before the processing operation, the mass metrology system 200 may obtain an initial image, typically obtained at multiple wavelengths, of the substrate 208 and an initial mass of the substrate 208 (e.g., by weighing the substrate 208 with the weighing module 204). After the processing operation, the mass metrology system 200 may obtain a new image of the substrate 208 and a new mass of the substrate 208. A distribution of the change in mass of the substrate 208 due to the processing operation may be determined based on the image/mass data before the processing operation and the image/mass data after the processing operation. For example, the distribution of the change in mass may be determined based on determining a distribution of a difference between the mass before and after the processing operation.

In some embodiments, the local mass change (thickness of the substrate) in mass may be correlated to the local change in reflectivity (transmissivity) and a global mass change of the substrate. If reflectivity of the substrate at wavelength λ and substrate thickness d is R(λ, d), a small change in the local thickness of the substrate, Δd(x, y), as a function of the coordinates x, y on the surface of the substrate may cause a local change in the reflectance

$$Δ R ( λ , x , y ) = ( \frac{\partial R ( λ , d )}{\partial d} ) Δ d ( x , y ) .$$

While the change ΔR(λ, x, y) is measured by detector 214, the ultimate objective may be to determine ΔR(λ, x, y). The change in the local thickness may be positive (Δd>0) when the material is added and negative (Δd<0) when the material is removed. (The same substrate may have some regions where the material is removed as well as other regions where the material is added.) A local mass change per unit area may be expressed as Δμ(x, y)=ρΔd(x, y), which represents a distribution of a change in mass across the substrate due to a processing operation which may add and/or remove material. To assist with determination of the value of the derivative of the reflectance over the thickness, the global mass change Δm may be expressed via the local thickness change as the integral

Δm=ρ∫dxdyΔd(x,y),

where ρ is the density of the added (or removed) material. In some embodiments, the derivative of the reflectance over the thickness may be approximated as a parameter (that depends on the wavelength) but is independent of thickness d (a linear reflectance model):

$${( \frac{\partial R ( λ , d )}{\partial d} )}^{- 1} \approx C ( λ ) .$$

In this linear model, the thickness change is related to the change in the reflectance as Δd(x, y)=C(λ)ΔR(λ, x, y) and the parameter C(λ) may be determined from the global mass change equation Δm=ρC(λ)∫dxdy ΔR(λ, x, y), which yields,

$$C ( λ ) = \frac{Δ m}{ρ \int d x d y Δ R ( λ , x , y )} .$$

Accordingly, the local thickness change may be determined from global mass metrology data (Δm) and the local optical data (ΔR(λ, x, y)) as follows:

$$Δ d ( x , y ) = \frac{Δ m Δ R ( λ , x , y )}{ρ \int {dx}^{′} {dy}^{′} Δ R ( λ , {x}^{′} , {y}^{′} )} .$$

In some embodiments, the local thickness change of the substrate may be determined (in the above or some other way) for multiple wavelengths λ₁, λ₂, λ₃, . . . and the thickness change Δd(x, y) may be obtained as an average (e.g., arithmetic average, geometric average, etc.) of thickness changes determined for individual wavelengths. The above example is intended for illustration purposes and it should be understood as many other (e.g., non-linear) schemes and functions may be used to correlate the local change in reflectivity (transmissivity) and a global mass change of the substrate with the local change in the thickness of the substrate.

In some embodiments, mass density for patterning films on substrates should be optimized to meet and/or maintain on-wafer performance requirements for these films. Further, the process settings that are used to achieve a target film density may have to be re-optimized over time, for example, at preventive maintenance steps. Mass metrology is a scalar measurement that directly depends on the mass density of a deposited film. Thus, mass metrology alone may not be sufficient to provide a spatially-resolved isolation of a source of variation in mass (e.g., the measured change in mass may be due to a change in film thickness, film uniformity, film density, etc.). On the other hand, optical metrology can be used to detect and distinguish variations in material properties resulting from changes in film thickness, uniformity, and density across the substrate, and may not measure mass density directly. Therefore, optical metrology and mass metrology provide complementary data and, when being used together, may provide additional information about variations of physical and optical composition of a film that is not available by each of the two techniques separately. For example, mass metrology may serve as a calibration technique for optical metrology. Conversely, optical metrology may provide information (e.g., via measurement of the optical density) about distribution of mass density across the extent of a film.

Optical and mass densities of a film may be related (e.g., correlated). Therefore, optical metrology measurements may be calibrated using mass density as a reference. Mass metrology may provide such a reference mass density when some parameters (e.g., thickness and uniformity) that affect the change in mass, e.g., when the film is deposited, are sufficiently controlled during a calibration process. The calibration can be performed for different processes, e.g., by altering respective process parameters in a controlled way. This calibration can be updated during any change in the process operation that is capable of altering the material properties or the mass density of the film. Thus, a combination of optical and mass metrologies may enable a process tool to measure and control film density in more efficient ways than optical metrology alone. Such combined techniques and tools may additionally be self-learning and self-optimizing.

Mass metrology may provide an independent measurement input to any model used to measure and/or predict physical properties (such as mass or optical density) of thin films (e.g., deposited, etched, milled, etc.). In some embodiments, the model may be a physical model, e.g., a model that is based on physical laws and other formalized physical relationships. In some embodiments, a model can be implemented using machine learning, e.g., as a machine learning model that uses inputs from both optical metrology and mess metrology. This offers a way to generate and train a predictive model that avoids specifying complex details and various material-dependent relationships between optical density (as measured by the reflectance and/or transmittance of a film) and mass density (as measured by mass metrology). In some embodiments, generating and training a predictive model can include applying this predictive model to an initial image of a sample. The initial image can be taken prior to a processing operation (e.g., a deposition operation, an etching operation, and so on) and one or more initial properties of the sample can be determined based on the initial image. The predictive model can then model the changes that are going to occur in the sample and predict one or more properties of the sample after the processing operation (e.g., new thickness of the sample, refractive index of the sample, and so on) is performed. A new image of the sample can be taken after the processing operation and updated properties of the sample can be determined based on the new image. A difference between the one or more updated properties of the sample and the one or more predicted properties of the sample can be determined. Various model parameters can then be adjusted, based on the identified difference. In one example, the one or more properties of the sample can include a deformation of the sample and the one or more predicted properties of the sample can include a predicted deformation of the sample. Correspondingly, adjusting the one or more parameters of the model can be based at least on a difference between the deformation of the sample and the predicted deformation of the sample.

Such a predictive machine learning model may additionally be enhanced with other (auxiliary) process sensor inputs (measurements) including a temperature sensor, a gas flow rate sensor, a pressure sensor, a radio frequency (RF) sensor, etc., to further improve the accuracy and precision of the model. The model can be trained using data (optical, mass, and auxiliary, if applicable) from multiple samples (e.g. films and substrates), including properly deposited films as well as suboptimal samples. The trained model may be used to monitor tool health (e.g., consistency of the tool and its adherence to target process parameters) and to predict thickness and uniformity results under various process conditions. Such a method, as described, may be referred to as virtual metrology.

In addition, mass metrology data can be used in a supervised machine learning model, which may add process settings into the model. This supervised machine learning model may be used to predict process operation (e.g., recipe) settings to achieve deposition of a thin film having desired characteristics on a substrate of a specific type. A predictive model that analyzes mass metrology data can be used to automatically re-optimize process parameters after performance of preventive maintenance activities, such as a chamber cleaning process. In one example, a predictive machine-learning model may be applied to at least an image of the sample taken before a processing operation, an image of the sample taken after the processing operation, a mass of the sample measured before the processing operation, and the mass of the sample measured after the processing operation.

As described above, the reflectance images of the substrate 208 may be obtained for a number of different wavelengths of light. The processing device 206 may ensure that the reflectance images per wavelength are properly and precisely aligned, which allows for determining the map of thickness and mass variations across the substrate 208. The mass metrology system 200 may be a true reflectometer which may be above to provide broadband, diffraction limited, telecentric images of its field of view, as described in U.S. Pat. No. 10,816,464 which is incorporated by reference in its entirety. Such a design may ensure that the illumination condition is independent of the location of the sample within the field of view, while maintaining spectral parfocality everywhere. Thus, images of the field of view may be in focus regardless of the wavelength that is instantaneously used to form the image. Reflectance analysis of the spectrally distinct images can therefore provide information regarding the thickness of the layers deposited or removed on a pixel-by-pixel, or region-by-region basis.

This information may be used to generate a map of layer thickness. The map may be reported on a per-die or region of die basis (e.g., for the entire substrate 208 or for a region of the substrate 208). In one embodiment, the reflectance images may be determined for the entire substrate without moving the imaging device or the substrate. For example, the large-field lenses 220 and 222 may be as large as (or slightly larger than) a diameter or size of the substrate such that a full image may be obtained. In other embodiments, the imaging device 202 may provide a field of view that is smaller than the substrate, and at least one of the imaging device or the substrate may be set up on a moving stage such that the entire substrate is scanned and an image of the entire substrate may be obtained. In other embodiments, it may not be necessary to scan the entire substrate, and only a portion of the substrate may be scanned and a reflectance image of only the portion of the substrate may be obtained. In cases where scanning the substrate requires moving one or more of the substrate 208 or the imaging device 202, the substrate may be scanned in a rectangular pattern, zigzag pattern, a raster scanning pattern, or any other geometric pattern.

In some embodiments, e.g., for semi-opaque films, optical metrology and mass metrology can measure dimensions for various structures fabricated into thicker semi-opaque films (e.g., diameter of a pillar or trench that is etched into a film). Although optical measurements with longer wavelengths may penetrate deeper into the film, a silicon substrate may become transparent at wavelengths for which the film is still opaque. In these cases, optical metrology may be limited to measuring dimensions in the upper region of the semi-opaque films where light (e.g., from a source) may scatter off the structure to a detected with an intensity that is sufficient to be measured with a detector. However, dimensions of the structure may also vary or change within the film at a depth within the film at which optical measurements may not be accurate. In these cases, the inclusion of mass metrology in conjunction with optical metrology, may allow for measuring dimension variations of the structures. In other words, optical metrology may provide a map of the dimension uniformity of a structure down to a certain depth in the semi-opaque film, mass metrology may be used to confirm that the measured dimension is uniform through the remaining depth of the semi-opaque film. Mass metrology may provide information as to whether or not the dimensions measured in the upper region of the semi-opaque film can be assumed to be the same for the remaining depth of the semi-opaque film (e.g. beyond the reach of optical metrology).

In another embodiment, a change in mass may be used to cross-check correctness of determination of physical properties, such as film thickness, height of ridges, depth of trenches, etc., that are computed from reflectance images, rather than cross checking the reflectance images themselves. Substrates that are in a high-vacuum environment may not be easily removed for performing measurements without affecting or damaging the substrate. For example, a nominally flat substrate with multiple thin films may be warped by stresses imparted from deposited films, which may lead to angular variations across the surface of the substrate. Such angular variations may produce optical distortions and may cause computation errors in optical models, which may not account for such angular variations when measuring light that is reflected from the surface of the substrate. Even though a vacuum chuck or electrostatic chuck may be used to flatten the substrate during a process operation, such techniques are typically complex and costly. In contrast, the integrated mass metrology may be used to cross-check the optical measurements of the reflectance images by comparing the expected mass increment from the change in the film thickness (due to a process operation) determined from the reflectance images to the actual change of the mass as detected with the mass metrology.

FIG. 2B illustrates integration of machine-learning methods of performance characteristics of a processed sample, according to one embodiment. Depicted in FIG. 2B is the mass metrology system 200 for providing uniformity data of a film on the substrate 208. The mass metrology system 200 may generate reflectance data 221 and mass metrology data 270 using detector 214 and weighing module 204, respectively. The data may include at least a first image of the sample, a second image of the sample, and a distribution of a change in thickness of the sample. Data 221 and 270 may be used as inputs into a machine-learning model (MLM) 230 to predict and control performance characteristics of the processed sample.

Reflectance data 221 and mass metrology data 270 output by detector 214 and weighing module 204 may be processed by one or more machine-learning models 230 (MLM). MLM 230 may be or include a decision-tree algorithm, a support vector machine, a deep neural network, or any combination thereof. Deep neural networks may include convolutional neural networks, recurrent neural networks (RNN) with one or more hidden layers, fully connected neural networks, long short-term memory neural networks, Boltzmann machines, and so on. MLM 230 may be trained to implement a specific technological process, including a specific substrate profile to be created over a specific time, a particular quality of the surface of substrate to be achieved, and so on. MLM 230 may use, as inputs, a reflectance data 221, metrology data 270, etc., specification of the technological process (not shown), a current timestamp (e.g., counted from the beginning of the technological process), and other suitable data. MLM 230 may output (e.g., in real time) process settings 240. Process settings 240 may include rates of deposition/etching, detector calibration, weighing module calibration, or any other applicable process setting. As process operations continue, process and calibration settings may be updated or adjusted. For example, if the weighing module measures a change in mass that is different from an expected change in mass, various processing settings may be updated to correct for the difference.

MLM 230 may be trained by MLM training engine 250. Training engine 250 may be located on the same manufacturing machine that hosts detector 214, weighing module 204, or on some external server that is communicatively coupled to the manufacturing machine. In some implementations, MLM training engine 250 may be located on a server that does not interact with the manufacturing machine, with the trained MLM being installed on the manufacturing machine after the training is performed. MLM training engine 250 may use training data 260, which may include data related to substrates of a similar type and processed in a similar (or the same) technological process. For example, training data 260 may include uniformity data as well as process settings implemented during previous processing of similar wafers. Training data 260 may further include annotations indicating correct and incorrect processing. In some implementations, MLM training engine 250 may train MLM 230 in real time on the same manufacturing machine using self-directed training iterations on a single (or multiple) batches of substrates.

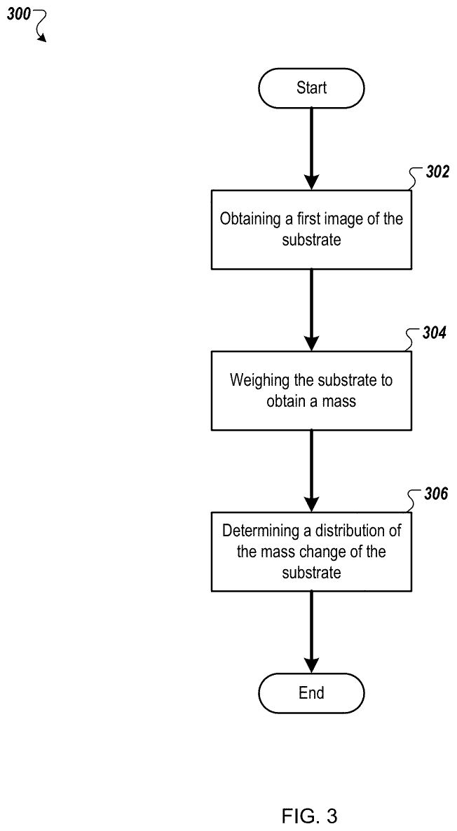

FIG. 3 is a flow diagram of a method 300 of determining a mass distribution of a sample according to one embodiment. “Sample” may refer to any substrate, wafer, one or more films deposited on a substrate, or any combination thereof. In some implementations, a substrate may remain unchanged (e.g., may have the same mass and/or optical properties) during processing operations whereas one or more films may be added, or any material may be removed from the films. The method 300 may be performed using systems and components shown in FIG. 1 or FIG. 2 or some combination thereof. Method 300 may be performed using one or more imaging devices and one or more weighing modules. The imaging device(s) and weighing module(s) may be configured as part of a mass metrology system, such as the mass metrology system 111 of FIG. 1 or the mass metrology system 200 of FIG. 2. Some or all blocks of the method 300 may be performed responsive to instructions from the computing device 118 or the microcontroller of electronic module 150, in some embodiments. The microcontroller of electronic module 150 may include one or more processing devices, such as central processing units (CPUs), application-specific integrated circuits (ASICs), field programmable gate arrays (FPGAs), digital signal processors (DSPs), network processors, or the like. The processing device(s) is (are) communicatively coupled to one or more memory devices, such as read-only memory (ROM), flash memory, static memory, dynamic random access memory (DRAM), and the like. The microcontroller of electronic module 150 may be a part of a desktop computer, a laptop computer, a workstation, a wearable device (e.g., a tablet, a smart phone, etc.), a cloud-based computing service, and the like. In some embodiments, the microcontroller 152 is a part of a larger network of computing devices. In some embodiments, an outside computing device communicating with the microcontroller of electronic module 150 is capable of reconfiguring (e.g., changing settings, updating memory, or otherwise reprogramming) the microcontroller 152. In some embodiments, the method 300 for determining the mass distribution of the substrate may be performed while a wafer is present inside a processing chamber, a transfer chamber, a load-lock chamber, and the like. In some embodiments, the method 300 may be implemented once a wafer has been removed from a respective chamber. The method 300 may be performed under conditions (e.g., at pressures and temperatures) that are similar to the actual conditions of the processing chamber during the manufacturing process. Accordingly, the manufacturing process may occur at low temperatures, or at temperatures that are less or significantly less than the room temperature. Alternatively, the manufacturing process may occur at the room temperature, above the room temperature, or significantly above the room temperature. In some embodiments, the pressure inside the chamber may be less or significantly less than the atmospheric pressure, including low vacuum or high vacuum conditions.

The method 300 may include obtaining a first image of the substrate (block 302). The first image of the sample may be obtained using a first instance of light. The sample may be a substrate (a wafer) with any number of materials deposited thereon (e.g., as films on the substrate) and any amount of material removed (e.g., from the substrate and/or films). The sample may have been subjected to a processing operation associated with a mass change of the sample. The processing operation includes at least one of a deposition operation or an etching operation. Obtaining the first image of the sample may include determining a reflectivity map of the sample with respect to the first instance of light. The method 300 may continue with weighing the sample to obtain a first mass of the sample (block 304). Obtaining the first image of the sample and weighing the sample may be performed concurrently (or at substantially the same time, e.g., before any other manipulations with the sample are performed). In one embodiment, weighing the sample may be performed in an environment having a pressure that is less than 50 Torr (in some embodiments, less than 5 Torr, less than 10 Torr, etc.). In other embodiments, weighing the sample may be performed in an environment having a pressure that is less than atmospheric pressure. The method 300 may continue with determining, based at least in part on the first image of the sample and the first mass of the sample, a distribution of the mass change of the sample (block 306). The distribution of the mass change of the sample may be due to the processing operation. The distribution of the mass change of the sample may be representative of a deformation of the sample.

In some embodiments, the method 300 may continue with obtaining a second image of the sample using a second instance of light that is different from the first instance of light. Determining the distribution of the mass change of the sample may be further based on the second image of the sample. For example, the first instance of light may have a first spectral distribution and the second instance of light may have a second distribution that is different from the first spectral distribution. Additionally or alternatively, a validity of optical measurements, such as the first image, the second image, or a comparison of the images may be based on either an initial mass of the sample or the distribution of the mass change of the sample.

In some embodiments, the method 300 may continue with obtaining a second image of the sample using a second instance of light prior to the processing operation. The method 300 may also include weighing the sample prior to the processing operation to obtain a second mass of the sample. Obtaining the second image of the sample and weighing the sample prior to the processing operation may be performed concurrently (or at substantially the same time, e.g., before any other manipulations with the sample are performed). Determining the distribution of the mass change of the sample may be further based on the second image of the sample and the second mass of the sample. Further, determining the distribution of the mass change of the sample may include determining a distribution of a difference between the first mass of the sample and the second mass of the sample over an area of the sample.

The systems and methods disclosed herein may be used not only for thickness variation monitoring during manufacturing, but may also be utilized for testing and development of various deposition and polishing processes. The advantages of the disclosed embodiments include, but are not limited to, the ability to inspect quality of processes and uniformity of sample surfaces and so on. In some embodiments, systems and methods disclosed may be used for determining mass distribution in objects other than samples, e.g. in process kits, substrate supports, edge rings, and the like. For example, an edge ring may be weighed and imaged prior to installation and then later again weighed and imaged (e.g., after retrieval by the robot 108) at a certain point in time. If the determined local mass loss (or thickness loss) at any point of the edge ring is determined to be beyond a threshold value, the edge ring may be scheduled for a replacement.

The thickness may be computed from a reflectance map, e.g., reflectance as a function of the location of the film for various wavelengths. Optical properties and film thickness may be cross correlated in an optical model. Therefore, a change in the optical properties of a film due to a process excursion may be misinterpreted, based on the reflectance data alone, as a change in film thickness. Therefore, a measurement of the change in mass (mass increment) can help to distinguish changes in film thickness from changes in optical properties of the film. In some embodiments, to compute the thickness, optical properties (e.g., real (n) and complex (k) parts of the refractive index) may be fixed in the corresponding physical model, and the thickness may be used as a fitting parameter.

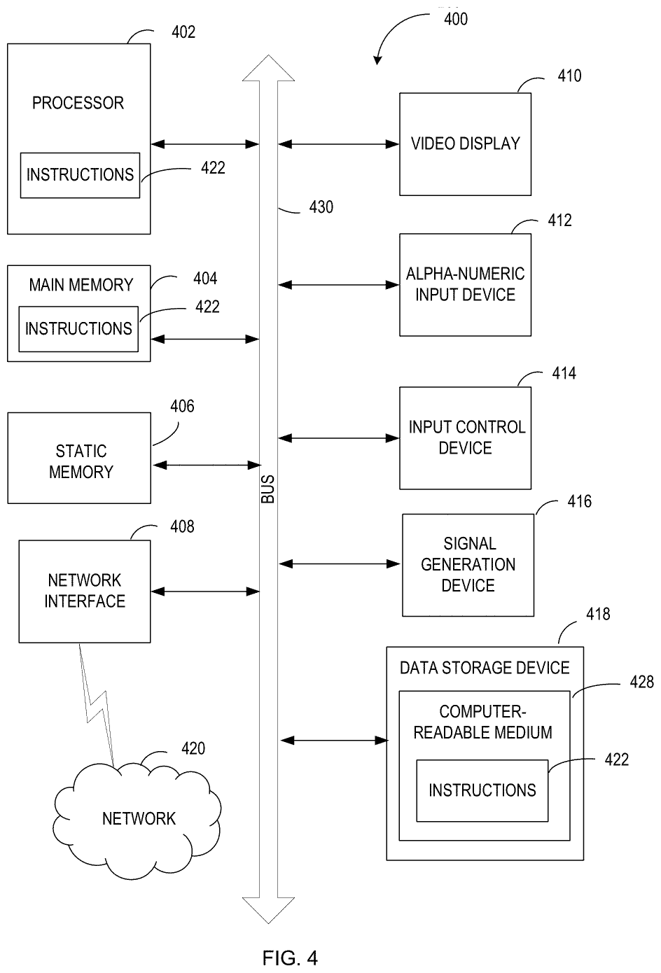

FIG. 4 depicts a block diagram of an example processing device 400 operating in accordance with one or more aspects of the present disclosure. The processing device 400 may be the computing device 118 of FIG. 1. Example processing device 400 may be connected to other processing devices in a local area network (LAN), an intranet, an extranet, and/or the Internet. The processing device 400 may be a personal computer (PC), a set-top box (STB), a server, a network router, switch or bridge, or any device capable of executing a set of instructions (sequential or otherwise) that specify actions to be taken by that device. Further, while only a single example processing device is illustrated, the term “processing device” shall also be taken to include any collection of processing devices (e.g., computers) that individually or jointly execute a set (or multiple sets) of instructions to perform any one or more of the methods discussed herein.

Example processing device 400 may include a processor 402 (e.g., a CPU), a main memory 404 (e.g., read-only memory (ROM), flash memory, dynamic random access memory (DRAM) such as synchronous DRAM (SDRAM), etc.), a static memory 406 (e.g., flash memory, static random access memory (SRAM), etc.), and a secondary memory (e.g., a data storage device 418), which may communicate with each other via a bus 430.

Processor 402 represents one or more general-purpose processing devices such as a microprocessor, central processing unit, or the like. More particularly, processor 402 may be a complex instruction set computing (CISC) microprocessor, reduced instruction set computing (RISC) microprocessor, very long instruction word (VLIW) microprocessor, processor implementing other instruction sets, or processors implementing a combination of instruction sets. Processor 402 may also be one or more special-purpose processing devices such as an application specific integrated circuit (ASIC), a field programmable gate array (FPGA), a digital signal processor (DSP), network processor, or the like. In accordance with one or more aspects of the present disclosure, processor 402 may be configured to execute instructions implementing method 300 of determining mass distributions.

Example processing device 400 may further comprise a network interface device 408, which may be communicatively coupled to a network 420. Example processing device 400 may further comprise a video display 410 (e.g., a liquid crystal display (LCD), a touch screen, or a cathode ray tube (CRT)), an alphanumeric input device 412 (e.g., a keyboard), an input control device 414 (e.g., a cursor control device, a touch-screen control device, a mouse), and a signal generation device 416 (e.g., an acoustic speaker).

Data storage device 418 may include a computer-readable storage medium (or, more specifically, a non-transitory computer-readable storage medium) 428 on which is stored one or more sets of executable instructions 422. In accordance with one or more aspects of the present disclosure, executable instructions 422 may comprise executable instructions implementing method 300 of determining mass distributions of samples due to processing operations.

Executable instructions 422 may also reside, completely or at least partially, within main memory 404 and/or within processor 402 during execution thereof by example processing device 400, main memory 404 and processor 402 also constituting computer-readable storage media. Executable instructions 422 may further be transmitted or received over a network via network interface device 408.

While the computer-readable storage medium 428 is shown in FIG. 4 as a single medium, the term “computer-readable storage medium” should be taken to include a single medium or multiple media (e.g., a centralized or distributed database, and/or associated caches and servers) that store the one or more sets of operating instructions. The term “computer-readable storage medium” shall also be taken to include any medium that is capable of storing or encoding a set of instructions for execution by the machine that cause the machine to perform any one or more of the methods described herein. The term “computer-readable storage medium” shall accordingly be taken to include, but not be limited to, solid-state memories, and optical and magnetic media.

It should be understood that the above description is intended to be illustrative, and not restrictive. Many other implementation examples will be apparent to those of skill in the art upon reading and understanding the above description. Although the present disclosure describes specific examples, it will be recognized that the systems and methods of the present disclosure are not limited to the examples described herein, but may be practiced with modifications within the scope of the appended claims. Accordingly, the specification and drawings are to be regarded in an illustrative sense rather than a restrictive sense. The scope of the present disclosure should, therefore, be determined with reference to the appended claims, along with the full scope of equivalents to which such claims are entitled.

The embodiments of methods, hardware, software, firmware or code set forth above may be implemented via instructions or code stored on a machine-accessible, machine readable, computer accessible, or computer readable medium which are executable by a processing element. “Memory” includes any mechanism that provides (i.e., stores and/or transmits) information in a form readable by a machine, such as a computer or electronic system. For example, “memory” includes random-access memory (RAM), such as static RAM (SRAM) or dynamic RAM (DRAM); ROM; magnetic or optical storage medium; flash memory devices; electrical storage devices; optical storage devices; acoustical storage devices, and any type of tangible machine-readable medium suitable for storing or transmitting electronic instructions or information in a form readable by a machine (e.g., a computer).

Reference throughout this specification to “one embodiment” or “an embodiment” means that a particular feature, structure, or characteristic described in connection with the embodiment is included in at least one embodiment of the disclosure. Thus, the appearances of the phrases “in one embodiment” or “in an embodiment” in various places throughout this specification are not necessarily all referring to the same embodiment. Furthermore, the particular features, structures, or characteristics may be combined in any suitable manner in one or more embodiments.

In the foregoing specification, a detailed description has been given with reference to specific exemplary embodiments. It will, however, be evident that various modifications and changes may be made thereto without departing from the broader spirit and scope of the disclosure as set forth in the appended claims. The specification and drawings are, accordingly, to be regarded in an illustrative sense rather than a restrictive sense. Furthermore, the foregoing use of embodiment, embodiment, and/or other exemplarily language does not necessarily refer to the same embodiment or the same example, but may refer to different and distinct embodiments, as well as potentially the same embodiment.

The words “example” or “exemplary” are used herein to mean serving as an example, instance, or illustration. Any aspect or design described herein as “example’ or “exemplary” is not necessarily to be construed as preferred or advantageous over other aspects or designs. Rather, use of the words “example” or “exemplary” is intended to present concepts in a concrete fashion. As used in this application, the term “or” is intended to mean an inclusive “or” rather than an exclusive “or.” That is, unless specified otherwise, or clear from context, “X includes A or B” is intended to mean any of the natural inclusive permutations. That is, if X includes A; X includes B; or X includes both A and B, then “X includes A or B” is satisfied under any of the foregoing instances. In addition, the articles “a” and “an” as used in this application and the appended claims should generally be construed to mean “one or more” unless specified otherwise or clear from context to be directed to a singular form. Moreover, use of the term “an embodiment” or “one embodiment” or “an embodiment” or “one embodiment” throughout is not intended to mean the same embodiment or embodiment unless described as such. Also, the terms “first,” “second,” “third,” “fourth,” etc. as used herein are meant as labels to distinguish among different elements and may not necessarily have an ordinal meaning according to their numerical designation.

What is claimed is:

1. A method comprising:
obtaining a first image of a sample using a first instance of light, wherein the sample has been subjected to a processing operation associated with a change of a thickness of the sample;
weighing the sample to obtain a first mass of the sample; and
determining, based at least in part on the first image of the sample and the first mass of the sample, one or more properties of the sample, wherein the one or more properties of the sample comprise at least one of:
the change of the thickness of the sample,
a change of an refractive index of the sample, or
a change of an optical density of the sample.

2. The method of claim 1, further comprising:
obtaining a second image of the sample using a second instance of light,
wherein determining the one or more properties of the sample is further based on the second image of the sample and comprises:
determining the change of the thickness of the sample at two or more locations of the sample.

3. The method of claim 2, wherein the first instance of light has a first spectral distribution and the second instance of light has a second spectral distribution different from the first spectral distribution.

4. The method of claim 1, further comprising:
accessing a second image of the sample, wherein the second image is obtained, prior to the processing operation, using a second instance of light; and
prior to the processing operation, weighing the sample to obtain a second mass of the sample; and
wherein determining the one or more properties of the sample is further based on the second image of the sample and the second mass of the sample.

5. The method of claim 4, wherein determining the one or more properties of the sample comprises:
determining a distribution of a difference between the first mass of the sample and the second mass of the sample over an area of the sample.

6. The method of claim 4, wherein determining the one or more properties of the sample further is further based on measurements obtained from one or more sensors comprising at least one of a temperature sensor, a gas flow rate sensor, a pressure sensor, or a radio frequency sensor.

7. The method of claim 4, further comprising:
applying a predictive model to at least the second image to generate one or more predicted properties of the sample;
identifying, based on the first image of the sample, a difference between the one or more properties of the sample and the one or more predicted properties of the sample; and
adjusting, based on the identified difference, one or more parameters of the predictive model.

8. The method of claim 7, wherein the one or more properties of the sample comprise a deformation of the sample and the one or more predicted properties of the sample comprise a predicted deformation of the sample, and wherein adjusting the one or more parameters of the model is based at least on a difference between the deformation of the sample and the predicted deformation of the sample.

9. The method of claim 4, wherein determining the one or more properties of the sample comprises:
applying a machine-learning model to at least the first image of the sample, the second image of the sample, the first mass of the sample, and the second mass of the sample.

10. The method of claim 1, wherein the processing operation comprises at least one of a material deposition operation or a material removal operation.

11. The method of claim 1, wherein obtaining the first image of the sample and weighing the sample are performed concurrently.

12. The method of claim 1, wherein weighing the sample is performed in an environment having a pressure less than 50 Torr.

13. The method of claim 1, wherein the first image of the sample comprises a reflectivity map of the sample obtained using the first instance of light.

14. The method of claim 1, wherein determining the one or more properties of the sample comprises determining at least one aberrant region of the sample.

15. A system comprising:
an imaging device configured to obtain a first image of a sample using a first instance of light, wherein the sample has been subjected to a processing operation associated with a mass change of the sample;
a mass measurement device configured to weigh the sample to obtain a first mass of the sample; and
a controller configured to determine, based at least in part on the first image of the sample and the first mass of the sample, one or more properties of the sample, wherein the one or more properties of the sample comprise at least one of:
the change of a thickness of the sample,
a change of an refractive index of the sample, or
a change of an optical density of the sample.

16. The system of claim 15, wherein the imaging device is further configured to:
obtain a second image of the sample using a second instance of light,
wherein to determine the one or more properties of the sample, the controller is further to:
determine, using the second image, the change of the thickness of the sample at two or more locations of the sample.

17. The system of claim 15, wherein the mass measurement device is configured to weigh the sample while the sample is within a vacuum environment.

18. The system of claim 15, wherein:
the imaging device is further configured to obtain, prior to the processing operation, a second image of the sample, wherein the second image is obtained using a second instance of light,
the mass measurement device is further configured to weigh the sample prior to the processing operation to obtain a second mass of the sample, and
the controller is configured to determine the one or more properties of the sample further based on the second image of the sample and the second mass of the sample.

19. The system of claim 15, further comprising a processing chamber configured to perform the processing operation, wherein the processing operation comprises at least one of a material deposition operation or a material removal operation.

20. A system comprising:
a robot comprising a movable robot blade configured to support a sample, wherein the sample has been subjected to a processing operation associated with a mass change of the sample;
an imaging reflectometer configured to obtain a first image of the sample using a first instance of light;
a scale configured to weigh the sample to obtain a first mass of the sample; and
a processing device configured to determine based at least in part on the first image of the sample and the first mass of the sample, one or more properties of the sample, wherein the one or more properties of the sample comprise at least one of:
the change of a thickness of the sample,
a change of an refractive index of the sample, or
a change of an optical density of the sample.

21. The system of claim 20, wherein:
the imaging reflectometer is further configured to obtain a second image of the sample, wherein the second image is obtained using a second instance of light prior to the processing operation,
the scale is further configured to weigh the sample prior to the processing operation to obtain a second mass of the sample, and
the processing device is configured to determine the one or more properties of the sample further based on the second image of the sample and the second mass of the sample.

22. The system of claim 20,
wherein the imaging reflectometer is further configured to obtain a second image of the sample using a second instance of light different from the first instance of light, the second instance of light having a spectral distribution different from a spectral distribution of the first light, and
wherein the processing device is further configured to determine the one or more properties of the sample based at least in part on the second image of the sample.
